(19) United States
(12) Patent Application Publication
(10) Pub. No.: US 2026/0214783 A1
(43) Pub. Date: Jul. 23, 2026

(54) ELECTRICAL CONNECTION UNIT

(71) Applicant: YAZAKI CORPORATION, Tokyo (JP)

(72) Inventor: Hirotaka Mukasa, Kakegawa-shi (JP)

(21) Appl. No.: 19/452,165

(22) Filed: Jan. 16, 2026

(30) Foreign Application Priority Data
Jan. 23, 2025 (JP) 2025-009689

(51) Int. Cl. H05K 1/02

(52) U.S. Cl. CPC H05K 1/0203

(57) ABSTRACT

The electrical connection unit including: a first circuit; a first heat dissipation member that covers a part of the first circuit, is thermally connected to the first circuit, and dissipates heat from the first circuit; a second circuit through which a current flows for a shorter time than through the first circuit; and a second heat dissipation member that covers a part of the second circuit, is thermally connected to the second circuit, and dissipates heat from the second circuit. The first exposure ratio is larger than the second exposure ratio, the first exposure ratio being the ratio of a portion exposed to an outside of the first heat dissipation member in a surface of the first circuit, and the second exposure ratio being the ratio of a portion exposed to an outside of the second heat dissipation member in a surface of the second circuit.

### BACKGROUND OF THE INVENTION

### Field of the Invention

Embodiments of the present invention relate to an electrical connection unit.

Priority is claimed on Japanese Patent Application No. 2025-009689 filed in Japan on January 23, 2025, the content of which is incorporated herein by reference.

### Description of the Related Art

In an electrical connection unit, it is known that electronic components such as relays and resistors are mounted on a mounting surface of a housing.

### Prior art document

### Patent document

Patent Document 1: Japanese Unexamined Patent Application, First Publication No. 2018-113184

### SUMMARY OF THE INVENTION

In the electrical connection unit, a plurality of circuits including the electronic components such as the relays and the resistors are mounted. The time when a current flows varies for each of the circuits. Under such circumstances, it is required to dissipate heat in a preferable heat dissipation mode according to the time when the current flows.

One embodiment provides an electrical connection unit capable of dissipating heat in a preferable heat dissipation mode according to a time when a current flows.

An electrical connection unit according to one embodiment is an on-vehicle electrical connection unit including: a first circuit; a first heat dissipation member that covers at least a part of the first circuit and is thermally connected to the first circuit to dissipate heat from the first circuit; a second circuit through which a current flows for a shorter time than through the first circuit; and a second heat dissipation member that covers at least a part of the second circuit and is thermally connected to the second circuit to dissipate heat from the second circuit, wherein the first exposure ratio is larger than the second exposure ratio, the first exposure ratio being the ratio of a portion exposed to an outside of the first heat dissipation member in a surface of the first circuit, the second exposure ratio being the ratio of a portion exposed to an outside of the second heat dissipation member in a surface of the second circuit.

According to the one embodiment, the heat can be dissipated in a preferable heat dissipation mode according to the time when the current flows.

### BRIEF DESCRIPTION OF THE DRAWINGS

FIG. 1 is a perspective view illustrating the schematic constitution of one example of an electrical connection unit according to an embodiment.

FIG. 2 is a schematic cross-sectional view illustrating a main part of the one example of the electrical connection unit according to the embodiment.

FIG. 3 is a schematic cross-sectional view illustrating a main part of an electrical connection unit according to a modification of the embodiment.

FIG. 4 is a schematic cross-sectional view illustrating a main part of an electrical connection unit according to a modification of the embodiment.

FIG. 5 is a schematic cross-sectional view illustrating a main part of an electrical connection unit according to a modification of the embodiment.

### DETAILED DESCRIPTION OF THE INVENTION

Hereinafter, embodiments will be described with reference to the drawings. In the following description, constitutions having same or similar functions are denoted by same reference signs. Redundant descriptions of these constitutions may be omitted. Note that constitutions described below do not limit the scope of the embodiment.

In the present disclosure, terms are defined as follows. A term “connection” is not limited to a mechanical connection, and may include an electrical connection. That is, the term “connection” is not limited to a case where two elements that are connection targets are directly connected, and may include a case where two elements that are connection targets are connected with another element interposed therebetween. A term “accommodation” is not limited to a case where an entire component is accommodated, and may include a case where only a part of the component is accommodated (a state in which a remaining part of the component protrudes). A term "cover" is not limited to a case where an entire object is covered, and may include a case where only a part of the object is covered. Terms “orthogonal” and “same” may include a case of “substantially orthogonal” and “substantially same”, respectively. A term “sheet-shaped” or “sheet” is not limited to a member having a thickness of 1 mm or more, and the term can also be applied to a member (so-called a film) having a thickness of less than 1 mm.

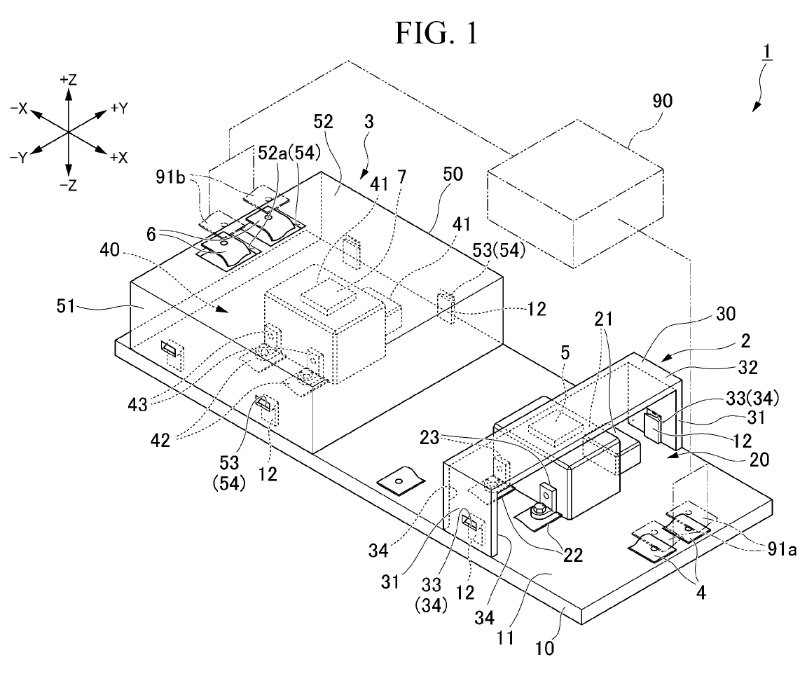

In the present disclosure, a +X direction, a -X direction, a +Y direction, a -Y direction, a +Z direction, and a -Z direction are defined as follows. As illustrated in FIG. 1, the X direction is one direction in a plane along a support surface 11 of a support 10 described later. The +X direction is one direction of the X direction. The -X direction is a direction opposite to the +X direction. Hereinafter, in a case where the +X direction and the -X direction are not distinguished from each other, the directions are simply referred to as the “X direction”. The Y direction is a direction intersecting with (for example, orthogonal to) the X direction in the plane along the support surface 11 of the support 10 described later. The +Y direction is one direction of the Y direction. The -Y direction is a direction opposite to the +Y direction. Hereinafter, in a case where the +Y direction and the -Y direction are not distinguished from each other, the directions are simply referred to as the “Y direction”. The +Z direction and the -Z direction are directions intersecting with (for example, orthogonal to) the X direction and the Y direction. The +Z direction is a direction that the support surface 11 of the support 10 faces. The -Z direction is a direction opposite to the +Z direction. Hereinafter, in a case where the +Z direction and the -Z direction are not distinguished, the directions will be simply referred to as the “Z direction”.

Hereinafter, in a case where the X direction and the Y direction are not distinguished, the directions may be referred to as a “horizontal direction”. Hereinafter, the Z direction may be referred to as a “vertical direction”. Hereinafter, a +Z direction side may be referred to as “upper”, and a -Z direction side may be referred to as “lower”. However, these expressions are expressions for convenience of description, and do not limit a gravity direction of an electrical connection unit 1 (an installation posture of the electrical connection unit 1). In addition, the X direction may be referred to as a first direction, the Y direction may be referred to as a second direction, and the Z direction may be referred to as a third direction.

### Embodiment

### 1. Constitution of Electrical Connection Unit

The electrical connection unit 1 (The on-vehicle electrical connection unit 1) is provided on the vehicle. The electrical connection unit 1 is, for example, an on-vehicle device mounted on a vehicle such as an electric vehicle (EV), a hybrid electric vehicle (HEV), or a plug-in hybrid electric vehicle (PHEV). The electrical connection unit 1 is connected to a plurality of external devices existing outside. The electrical connection unit 1 relays connection between the plurality of external devices (hereinafter, also referred to “products”). For example, the external devices may include a battery pack, a load, a charger, and the like. The battery pack is mounted on a vehicle. The load is a device including an inverter or the like for driving a motor of the vehicle driven by using a power stored in the battery pack. The charger is a device for supplying a power for charging the battery pack. The electrical connection unit 1 may also be referred to as an “electrical connection box” or a “junction box”, for example. However, the electrical connection unit 1 is not limited to a box-shaped device.

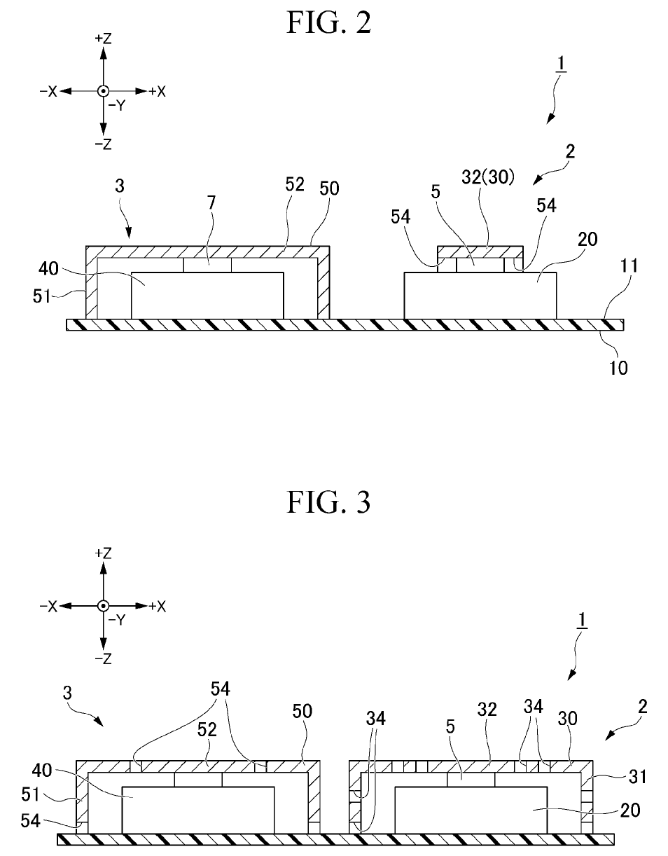

As illustrated in FIGS. 1 and 2, the electrical connection unit 1 includes the support 10, a first constituent body 2, and a second constituent body 3. In the present embodiment, the first constituent body 2 and the second constituent body 3 are mounted on the same support 10. Note that in FIG. 2, for example, a state is schematically illustrated where a first circuit 20 is covered with a first heat dissipation member 30 and a second circuit 40 is covered with a second heat dissipation member 50, and a part of the constitution is omitted or simplified. For example, in FIG. 2, a detailed constitution of the first circuit 20 (first electronic components 21, first bus bars 22, first connection components 23, and the like) is omitted, and a detailed constitution of the second circuit 40 (second electronic components 41, second bus bars 42, second connection components 43, and the like) is omitted.

### Support

The support 10 supports the first constituent body 2 and the second constituent body 3, which will be described later. The support 10 is, for example, a base plate formed in a plate shape extending in the horizontal direction. Note that in the present disclosure, the “plate shape ” is not limited to a completely flat shape, and may include a case where a fixing structure, a rib, or the like protruding in the Z direction partially exist. In the present embodiment, the support 10 has a plate shape along the X direction and the Y direction. A surface of the support 10 facing the +Z direction side (the upper side) is defined as the support surface 11. The support 10 is made of, for example, a synthetic resin and has an insulating property. Further, the support 10 has a plurality of claw portions 12. The plurality of claw portions 12 are located on an outer periphery of the support 10. Each of the claw portions 12 protrudes in the +Z direction. The claw portions 12 are engaged with first engagement portions 33 of the first heat dissipation member 30 and second engagement portions 53 of the second heat dissipation member 50 described later.

### First Constituent Body

The first constituent body 2 is mounted on an end portion of the support surface 11 of the support 10 on the +X direction side. The first constituent body 2 includes the first circuit 20, first external bus bars 4, a first heat transfer member 5, and the first heat dissipation member 30.

### First Circuit

The first circuit 20 is mounted on the support surface 11 of the support 10. The first circuit 20 is a circuit through which a current flows for a longer time than through the second circuit 40 described later. The first circuit 20 is, for example, a heat dissipation circuit for supplying an electric power for driving the vehicle from a battery 90. In addition, the first circuit 20 is also a drive circuit such as a motor. The first circuit 20 has, for example, the first electronic components 21, the first bus bars 22, and the first connection components 23. The plurality of first electronic components 21 are installed on the support surface 11. The first bus bars 22 are mounted on the support 10 and exposed on the support surface 11. Each of the first electronic components 21 is electrically connected to each of the first bus bars 22 via, for example, each of the first connection components 23. Note that in the illustrated example, a constitution of the first circuit 20 is appropriately omitted. The illustrated example is merely one example, and the present invention is not limited thereto. Numbers, arrangements, and shapes of the first electronic components 21, the first bus bars 22, and the first connection components 23 can be appropriately changed. In addition, the first circuit 20 may include a constitution other than the first electronic components 21, the first bus bars 22, and the first connection components 23. In addition, the first circuit 20 may include one constituent component (for example, one first electronic component 21).

Each of the first electronic components 21 is an important component for exerting a function of relaying connection between the plurality of external devices among the electronic components included in the electrical connection unit 1. Each of the first electronic components 21 may be, for example, an electronic component required for the electrical connection unit 1 in common to different products to which the electrical connection unit 1 is applied. The plurality of first electronic components 21 may include, for example, a relay (for example, a mechanical relay or a semiconductor relay). The plurality of first electronic components 21 may include, for example, a relay capable of switching between conduction and disconnection of a largest current among relays mounted on the electrical connection unit 1. Each of the first electronic components 21 is electrically connected to at least one of the plurality of first bus bars 22. Each of the first electronic components 21 may be electrically connected to each of the first bus bars 22 via, for example, each of the first connection components 23.

### First External Bus Bar

The plurality of first external bus bars 4 are provided. The first external bus bars 4 are also referred to as first external connection bus bars or first external connection routing members. The first external bus bars 4 are each a bus bar for electrically connecting the battery 90 for driving the vehicle and the first circuit 20. In the illustrated example, one end of the first external bus bar 4 is connected to one end of the first bus bar 22, and another end of the first external bus bar 4 is connected to a terminal 91a of the battery 90.

### First Heat Transfer Member

The first heat transfer member 5 is a member that promotes heat transfer from the first circuit 20 to the first heat dissipation member 30 described later. The first heat transfer member 5 is placed so as to fill a space between the first circuit 20 and the first heat dissipation member 30. In the illustrated example, the first heat transfer member 5 is provided on an upper surface of one of the first electronic components 21 constituting the first circuit 20, and is in close contact with both the first circuit 20 and the first heat dissipation member 30. The first heat transfer member 5 is, for example, a heat transfer sheet (for example, a thermally conductive silicone sheet) having elasticity. However, the first heat transfer member 5 is not limited to the above example, and may be a heat transfer member formed of a thermally conductive gel or another material. In addition, the first heat transfer member 5 may be provided on a component of the first circuit 20 other than the first electronic component 21.

### First Heat Dissipation Member

The first heat dissipation member 30 is a member that covers at least a part of the first circuit 20 and dissipates heat (for example, Joule heat) generated by the first circuit 20 by being thermally connected to the first circuit 20. At least a part of the first heat dissipation member 30 is made of, for example, metal (for example, aluminum or aluminum alloy). In the illustrated example, the entire first heat dissipation member 30 is made of metal. In the present embodiment, the first heat dissipation member 30 accommodates the first circuit 20 therein. The first heat dissipation member 30 is a U-shaped member that opens toward the -Z direction side as viewed in the X direction. In addition, the first heat dissipation member 30 is also open on both sides in the X direction. The first heat dissipation member 30 has first side walls 31 and a first upper wall 32. Each of the first side walls 31 is provided at each end edge in the Y direction of the support 10. The pair of first side walls 31 faces each other in the Y direction. Each of the first side walls 31 is formed in a rectangular plate shape extending in the +Z direction from the support surface 11 of the support 10. The first upper wall 32 connects upper ends of the pair of first side walls 31. The first upper wall 32 is formed in a rectangular shape extending in the Y direction. When viewed from the +Z direction, the first circuit 20 is disposed such that both ends in the X direction of the first circuit 20 (for example, both ends of the first electronic component 21) are located on both outer sides in the X direction of the first upper wall 32. In this manner, the first heat dissipation member 30 covers a part of the first circuit 20. In addition, the first heat transfer member 5 is in close contact with a lower surface of the first upper wall 32.

In addition, each of the first engagement portions 33 is formed at a lower end of each of the first side walls 31. In the illustrated example, the first engagement portion 33 is an opening penetrating the first side wall 31 in the horizontal direction. Each of the first engagement portions 33 is caught by a tip of each of the claw portions 12 of the support 10. By this catch, the first heat dissipation member 30 is held by the support 10. The first engagement portion 33 is not limited to the opening, and may be a recess that is recessed from an inner peripheral surface of the first side wall 31. On the other hand, each of the claw portions 12 may have any lock structure as long as it can be caught by the corresponding first engagement portion 33.

### Second Constituent Body

The second constituent body 3 is mounted on an end portion of the support surface 11 of the support 10 on the -X direction side. The second constituent body 3 includes the second circuit 40, second external bus bars 6, a second heat transfer member 7, and the second heat dissipation member 50.

### Second Circuit

The second circuit 40 is mounted on the support surface 11 of the support 10. The second circuit 40 is a circuit through which a current flows for a shorter time than through the first circuit 20. The second circuit 40 is, for example, a heat dissipation circuit used for charging the battery 90. The second circuit 40 has, for example, the second electronic components 41, the second bus bars 42, and the second connection components 43. The plurality of second electronic components 41 are installed on the support surface 11. The second bus bars 42 are mounted on the support 10 and exposed on the support surface 11. Each of the second electronic components 41 is electrically connected to each of the second bus bars 42 via, for example, each of the second connection components 43. Note that in the illustrated example, a constitution of the second circuit 40 is appropriately omitted. The illustrated example is merely one example, and the present invention is not limited thereto. Numbers, arrangements, and shapes of the second electronic components 41, the second bus bars 42, and the second connection components 43 can be appropriately changed. In addition, the second circuit 40 may include a constitution other than the second electronic components 41, the second bus bars 42, and the second connection components 43. In addition, the second circuit 40 may include one constituent component (for example, one second electronic component 41).

Each of the second electronic components 41 is an important component for exerting a function of relaying connection between the plurality of external devices among the electronic components included in the electrical connection unit 1. Each of the second electronic components 41 may be, for example, an electronic component required for the electrical connection unit 1 in common to different products to which the electrical connection unit 1 is applied. The plurality of second electronic components 41 may include, for example, a relay (for example, a mechanical relay or a semiconductor relay). The plurality of second electronic components 41 may include, for example, a relay capable of switching between conduction and disconnection of a largest current among the relays mounted on the electrical connection unit 1. Each of the second electronic components 41 is electrically connected to at least one of the plurality of second bus bars 42. Each of the second electronic components 41 may be electrically connected to each of the second bus bars 42 via, for example, each of the second connection components 43.

### Second External Bus Bar

The plurality of second external bus bars 6 are provided. The second external bus bars 6 are also referred to as second external connection bus bars or second external connection routing members. The second external bus bars 6 are each a bus bar for electrically connecting the battery 90 for driving the vehicle and the second circuit 40. In the illustrated example, each of the second external bus bars 6 is a three-dimensional routing bus bar extending in the +Z direction from the support surface 11. One end of the second external bus bar 6 is accommodated inside the second heat dissipation member 50 described later, and is connected to one end of the second bus bar 42. Another end of the second external bus bar 6 is located outside the second heat dissipation member 50 and is connected to a terminal 91b of the battery 90.

### Second Heat Transfer Member

The second heat transfer member 7 is a member that promotes heat transfer from the second circuit 40 to the second heat dissipation member 50 described later. The second heat transfer member 7 is placed so as to fill a space between the second circuit 40 and the second heat dissipation member 50. In the illustrated example, the second heat transfer member 7 is provided on an upper surface of one of the second electronic components 41 constituting the second circuit 40, and is in close contact with both the second circuit 40 and the second heat dissipation member 50. The second heat transfer member 7 is, for example, a heat transfer sheet (for example, a thermally conductive silicone sheet) having elasticity. However, the second heat transfer member 7 is not limited to the above example, and may be a heat transfer member formed of a thermally conductive gel or another material. In addition, the second heat transfer member 7 may be provided on a component of the second circuit 40 other than the second electronic component 41.

### Second Heat Dissipation Member

The second heat dissipation member 50 is a member that covers at least a part of the second circuit 40 and dissipates heat (for example, Joule heat) generated by the second circuit 40 by being thermally connected to the second circuit 20. At least a part of the second heat dissipation member 50 is made of, for example, metal (for example, aluminum or aluminum alloy). In the illustrated example, the entire second heat dissipation member 50 is made of metal. In the present embodiment, the second heat dissipation member 50 accommodates the second circuit 40 therein. The second heat dissipation member 50 is a box-shaped case opened to the -Z direction side. The second heat dissipation member 50 has second side walls 51 and a second upper wall 52. The second side walls 51 are formed in a rectangular frame shape when viewed from the +Z direction. The second side walls 51 surround the second circuit 40 from the horizontal direction. The second side walls 51 extend in the +Z direction from the support surface 11 of the support 10. The second upper wall 52 covers an upper opening of the second side walls 51. The second heat dissipation member 50 covers the entire second circuit 40. With such a shape, ventilation of the second heat dissipation member 50 is smaller than that of the first heat dissipation member 30. In addition, the second heat transfer member 7 is in close contact with a lower surface of the second upper wall 52.

In addition, each of the second engagement portions 53 is formed at a lower end of each of the second side walls 51. In the illustrated example, the second engagement portion 53 is an opening penetrating the second side wall 51 in the horizontal direction. Each of the second engagement portions 53 is caught by a tip of each of the claw portions 12 of the support 10. By this catch, the second heat dissipation member 50 is held by the support 10. The second engagement portion 53 is not limited to the opening, and may be a recess that is recessed from an inner peripheral surface of the second side wall 51. On the other hand, each of the claw portions 12 may have any lock structure as long as it can be caught by the corresponding second engagement portion 53.

In addition, the second upper wall 52 is provided with lead-out openings 52a penetrating the second upper wall 52. The other end (the end portion on the side connected to the battery 90) of the second external bus bar 6 described above is led out from each of the lead-out openings 52a to an outside of the second heat dissipation member 50. The lead-out opening 52a is formed, for example, at a position not overlapping the second circuit 40 in a penetrating direction of the lead-out opening 52a.

Hereinafter, the ratio of an exposed portion of a surface of the first circuit 20 is referred to as the first exposure ratio, and the ratio of an exposed portion in a surface of the second circuit 40 is referred to as the second exposure ratio. The exposed portion of the surface of the first circuit 20 is a portion of the surface of the first circuit 20 that is exposed to an outside without being covered with the support 10 and the first heat dissipation member 30, and the exposed portion of the surface of the second circuit 40 is a portion of the surface of the second circuit 40 that is exposed to the outside without being covered with the support 10 and the second heat dissipation member 50. Note that the exposed portion may be a portion overlapping with the penetrating direction of the opening portion (the hole or the cut-out) penetrating each of the heat dissipation members (the first heat dissipation member 30, the second heat dissipation member 50). In the present embodiment, the first heat dissipation member 30 and the second heat dissipation member 50 are formed in the above-described shapes, so that the first exposure ratio is larger than the second exposure ratio. In addition, the first heat dissipation member 30 and the second heat dissipation member 50 are formed such that a surface area of the second heat dissipation member 50 is larger than a surface area of the first heat dissipation member 30.

### 3. Advantages

In the present embodiment, the electrical connection unit 1 is an on-vehicle electrical connection unit 1. The electrical connection unit 1 includes the first circuit 20, the first heat dissipation member 30, the second circuit 40, and the second heat dissipation member 50. The first heat dissipation member 30 covers at least a part of the first circuit 20. The first heat dissipation member 30 is thermally connected to the first circuit 20 and dissipates the heat from the first circuit 20. In the second circuit 40, a current flows for a shorter time than in the first circuit 20. The second heat dissipation member 50 covers at least a part of the second circuit 40. The second heat dissipation member 50 is thermally connected to the second circuit 40 and dissipates the heat of the second circuit 40. The first exposure ratio is larger than the second exposure ratio. The first exposure ratio is the ratio of the portion exposed to the outside of the first heat dissipation member 30 in the surface of the first circuit 20. The second exposure ratio is the ratio of the portion exposed to the outside of the second heat dissipation member 50 in the surface of the second circuit 40. With such a constitution, the first heat dissipation member 30 that dissipates the heat from the first circuit 20 through which a current flows for a long time can improve ventilation and improve air fluidity. Therefore, it is possible to suppress occurrence of heat confinement inside the first heat dissipation member 30. In addition, as for the second heat dissipation member 50 that dissipates the heat of the second circuit 40 through which a current flows for a short time, the heat dissipation area of the second heat dissipation member 50 can be increased. Therefore, cooling performance of the second heat dissipation member 50 can be improved. Accordingly, it is possible to dissipate the heat in a preferable heat dissipation mode in each of the first circuit 20 through which the current flows for a long time and the second circuit 40 through which the current flows for a short time. That is, the heat can be dissipated in a preferable heat dissipation mode according to the time when the current flows.

In the present embodiment, the first circuit 20 is a discharging circuit for supplying an electric power for driving the vehicle from the battery 90. The second circuit 40 is a charging circuit used for charging the battery 90. With such a constitution, it is possible to dissipate the heat in a heat dissipation mode in which ventilation is prioritized for the discharging circuit in which a current flows for a short time. In addition, it is possible to dissipate the heat in a heat dissipation mode in which heat dissipation is prioritized for the charging circuit in which a current flows for a long time.

In the present embodiment, the first heat dissipation member 30 covers a part of the first circuit 20, and the second heat dissipation member 50 covers the entire second circuit 40. With such a constitution, only by providing the above-described simple shape difference between the first heat dissipation member 30 and the second heat dissipation member 50, the first heat dissipation member 30 can be formed in the shape that dissipates the heat in the heat dissipation mode in which the ventilation is prioritized, and the second heat dissipation member 50 can be formed in the shape that dissipates the heat in the heat dissipation mode in which the heat dissipation is prioritized.

In the present embodiment, the surface area of the second heat dissipation member 50 is larger than the surface area of the first heat dissipation member 30. With such a constitution, the heat dissipation area of the second heat dissipation member 50 can be made larger than that of the heat dissipation member of the first heat dissipation member 30.

In the present embodiment, the electrical connection unit 1 includes the first heat transfer member 5 and the second heat transfer member 7. The first heat transfer member 5 is placed so as to fill a space between the first circuit 20 and the first heat dissipation member 30. The first heat transfer member 5 promotes the heat transfer from the first circuit 20 to the first heat dissipation member 30. The second heat transfer member 7 is placed so as to fill the space between the second circuit 40 and the second heat dissipation member 50. The second heat transfer member 7 promotes the heat transfer from the second circuit 40 to the second heat dissipation member 50. With such a constitution, both the heat dissipation of the first circuit 20 and the heat dissipation of the second circuit 40 are improved.

### Modifications

Next, several modifications will be described. Note that constitutions other than those described below in each modification are the same as the constitutions of the above-described embodiment.

The first heat dissipation member 30 may be, for example, a plate-shaped member that is installed on one surface of the first electronic component 21 (for example, the upper surface of the first electronic component 21) and extends in the horizontal direction.

In addition, as illustrated in FIG. 3, the first heat dissipation member 30 may be a box-shaped case opened to the -Z direction side, similarly to the second heat dissipation member 50. Note that FIG. 3 is a schematic view corresponding to FIG. 2. That is, in this modification, the first heat dissipation member 30 covers the entire first circuit 20. The first side walls 31 are formed so as to surround the first circuit 20 from the horizontal direction, and the first upper wall 32 covers the opening above the first side walls 31. However, the first heat dissipation member 30 has one or more first opening portions 34 that are through holes or cut-outs provided in the first heat dissipation member 30. In addition, the second heat dissipation member 50 has one or more second opening portions 54 that are through holes or cut-outs provided in the second heat dissipation member 50. Here, the ratio of the one or more first opening portions 34 in the first heat dissipation member 30 is referred to as a first opening ratio, and the ratio of the one or more second opening portions 54 in the second heat dissipation member 50 is referred to as a second opening ratio. At this time, the first heat dissipation member 30 and the second heat dissipation member 50 are formed such that the first opening ratio is larger than the second opening ratio. For example, the first heat dissipation member 30 and the second heat dissipation member 50 are formed in a substantially same shape and a substantially same size, and the first opening portions 34 are formed more than the second opening portions 54. In addition, the first opening portions 34 are formed so as to have an opening area larger than an opening area of the second opening portions 54. According to such a constitution, by simple processing in which a difference between the first opening ratio and the second opening ratio is only set, the first heat dissipation member 30 can have a shape that dissipates heat in a heat dissipation mode in which the ventilation is prioritized, and the second heat dissipation member 50 can have a shape that dissipates heat in a heat dissipation mode in which the heat dissipation is prioritized.

Note that the relationship in which the first opening ratio is larger than the second opening ratio may be applied to the above-described embodiment illustrated in FIGS. 1 and 2. In this case, in the U-shaped first heat dissipation member 30, each of the edge portions on both sides in the X direction may be one of the first opening portions 34 opened on both the sides in the X direction, and each of the first engagement portions 33 may be one of the first opening portions 34. In addition, in this case, in the box-shaped second heat dissipation member 50, each of the second engagement portions 53 and the lead-out openings 52a may be one of the second opening portions 54.

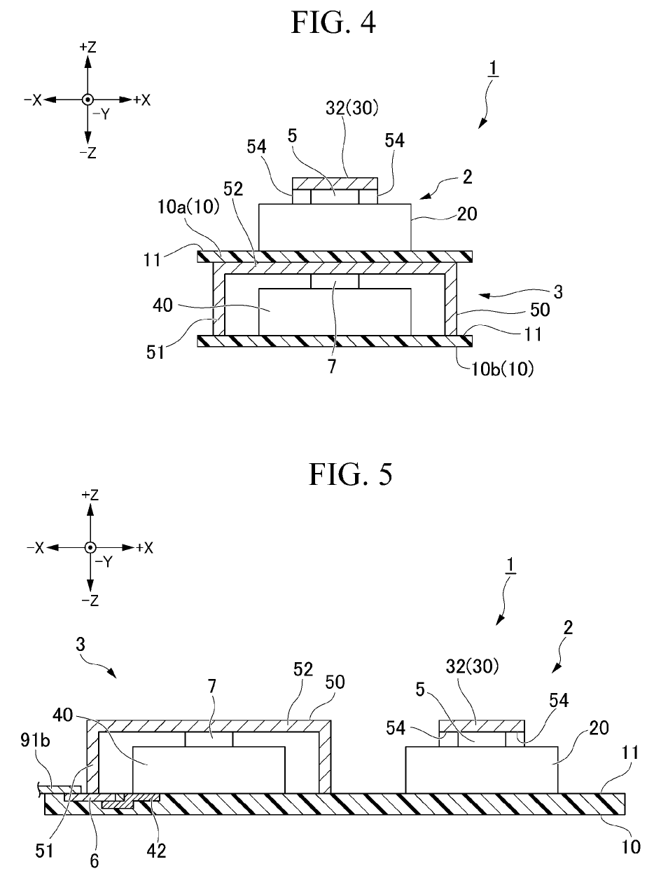

Moreover, as illustrated in FIG. 4, the first constituent body 2 and the second constituent body 3 may be provided separately from each other. Note that FIG. 4 is a schematic view corresponding to FIG. 2. In an illustrated example, a plurality of supports 10 are provided, and the plurality of supports 10 includes a first support 10a and a second support 10b. The first constituent body 2 is supported by, for example, the first support 10a, and the second constituent body 3 is supported by, for example, the second support 10b. In addition, for example, the first support 10a is disposed to overlap the second upper wall 52 of the second heat dissipation member 50.

In addition, as illustrated in FIG. 5, for example, the second external bus bars 6 connecting the second circuit 40 and the battery 90 may be led out from a lower side of the second heat dissipation member 50, and openings may be formed in the second heat dissipation member 50 as little as possible. Note that FIG. 5 is a schematic view corresponding to FIG. 2.

The embodiment and modifications have been described above. However, the embodiment and the modifications are not limited to the examples described above. For example, a plurality of embodiments may be implemented in combination with each other.

While preferred embodiments of the invention have been described and illustrated above, it should be understood that these are exemplary examples of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 electrical connection unit

2 first constituent body

3 second constituent body

4 first external bus bar

5 first heat transfer member

6 second external bus bar

7 second heat transfer member

10 support

11 support surface

10a first support

10b second support

12 claw portion

20 first circuit

21 first electronic component

22 first bus bar

23 first connection component

30 first heat dissipation member

31 first side wall

32 first upper wall

33 first engagement portion

34 first opening portion

40 second circuit

41 second electronic component

42 second bus bar

43 second connection component

50 second heat dissipation member

51 second side wall

52 second upper wall

52a lead-out opening

53 second engagement portion

54 second opening portion

90 battery

91a terminal

91b terminal

What is claimed is:

1. An electrical connection unit provided on a vehicle, comprising:
a first circuit;
a first heat dissipation member that covers at least a part of the first circuit, is thermally connected to the first circuit, and dissipates heat from the first circuit;
a second circuit through which a current flows for a shorter time than through the first circuit; and
a second heat dissipation member that covers at least a part of the second circuit, is thermally connected to the second circuit, and dissipates heat from the second circuit,
wherein a first exposure ratio is larger than a second exposure ratio, the first exposure ratio being a ratio of a portion exposed to an outside of the first heat dissipation member in a surface of the first circuit, and the second exposure ratio being a ratio of a portion exposed to an outside of the second heat dissipation member in a surface of the second circuit.

2. The electrical connection unit according to claim 1, wherein
the first circuit is a discharging circuit for supplying an electric power for driving the vehicle from a battery, and
the second circuit is a charging circuit used for charging the battery.

3. The electrical connection unit according to claim 1, wherein
the first heat dissipation member covers a part of the first circuit, and
the second heat dissipation member covers the entire second circuit.

4. The electrical connection unit according to claim 1, wherein
the first heat dissipation member covers the entire first circuit and has one or more first opening portions that are through holes or cut-outs provided in the first heat dissipation member,
the second heat dissipation member covers the entire second circuit, and has one or more second opening portions that are through holes or cut-outs provided in the second heat dissipation member, and
a first opening ratio is larger than a second opening ratio, the first opening ratio being a ratio of the one or more first opening portions in the first heat dissipation member, and the second opening ratio being a ratio of the one or more second opening portions in the second heat dissipation member.

5. The electrical connection unit according to claim 1, wherein
a surface area of the second heat dissipation member is larger than a surface area of the first heat dissipation member.

6. The electrical connection unit according to claim 1, comprising:
a first heat transfer member that is placed so as to fill a space between the first circuit and the first heat dissipation member and promotes heat transfer from the first circuit to the first heat dissipation member; and
a second heat transfer member that is placed so as to fill a space between the second circuit and the second heat dissipation member and promotes heat transfer from the second circuit to the second heat dissipation member.
